(19) United States
(12) Patent Application Publication
(10) Pub. No.: US 2006/0286759 A1
(43) Pub. Date: Dec. 21, 2006

(54) Metal oxide semiconductor (MOS) device having both an accumulation and a enhancement mode transistor device on a similar substrate and a method of manufacture therefor

(75) Inventors: Weize Xiong, Austin, TX (US); Rinn Cleavelin, Dallas, TX (US)

Correspondence Address: TEXAS INSTRUMENTS INCORPORATED, P O BOX 655474, M/S 3999, DALLAS, TX, 75265, US

(73) Assignee: Texas Instruments, Inc., Dallas, TX (US)

(21) Appl. No.: 11/157,224

(22) Filed: Jun. 21, 2005

(51) Int. Cl. H01L 21/331

(52) U.S. Cl. 438/351

(57) ABSTRACT

The present invention provides a metal oxide semiconductor (MOS) device, a method of manufacture therefore, and an integrated circuit including the same. The metal oxide semiconductor (MOS) device (100), without limitation, may include a first accumulation mode transistor device (120, 160) located over or in a substrate (110), as well as a second enhancement mode transistor (140, 180) device located over or in the substrate (110).

### TECHNICAL FIELD OF THE INVENTION

The present invention is directed, in general, to a metal oxide-semiconductor (MOS) device and, more specifically, to metal oxide semiconductor (MOS) device having both an accumulation and an enhancement mode transistor device on a similar substrate, a method of manufacture therefore, and an integrated circuit including the same.

### BACKGROUND OF THE INVENTION

The ability to dope polysilicon gates to different degrees allows one to adjust the work function of gate electrode materials to particular types of metal oxide semiconductor (MOS) transistors. It is desirable to adjust the work function of a gate electrode to be close to either the conduction band or the valence band of silicon, because this specifies the threshold voltage (Vₜ) of the transistor, thereby facilitating a desired drive current. For instance, dual work function gates are advantageously used in semiconductor devices, such as complementary metal oxide silicon (CMOS) transistor devices, having both PMOS and NMOS transistors. The use of doped polysilicon gates becomes problematic, however, as the dimensions of gate electrodes and gate insulators are reduced.

Polysilicon gate electrodes can accommodate only a finite amount of dopants. This limitation can result in a depletion of gate charge carriers at the interface between the gate electrode and gate dielectric, when the gate electrode is biased to invert the channel. Consequently, the electrical thickness of the gate stack is substantially increased, thereby deteriorating the performance characteristics of the transistor, such as reducing the drive current and slowing switching speeds. For instance, the effective electrical thickness of a gate dielectric in some PMOS transistors can increase from about 1.0 nanometer during accumulation mode, to about 1.8 nanometers during inversion mode. Depletion of the polysilicon gate is a fundamental issue that limits further scaling of MOS devices.

In addition, when high-k gate dielectrics are used with polysilicon a threshold voltage (Vₜ) offset of up to 700 mV is observed for PMOS devices. This offset is associated with dopant, for example boron, diffusion and interaction with the gate dielectric. At present, there is no effective way to control for this threshold voltage (Vₜ) offset problem.

Metal gate electrodes are an attractive alternative to polysilicon because they have a larger supply of charge carriers than doped polysilicon gate electrodes. When a metal gate is biased to invert the channel, there is no substantial depletion of carriers at the interface between the metal gate and gate dielectric. Accordingly, the transistor's performance is not deteriorated because the electrical thickness of the gate stack is not increased. The manufacture of semiconductor transistors having adjustable dual work function metal gate electrodes has been troublesome, however.

Ideally, dual work function metal gate electrodes should be compatible with conventional gate dielectric materials and have suitably adjustable and stable work functions. It is challenging, however, to find such metals. For instance, there have been attempts to use fully nickel silicided polysilicon as the gate electrode for MOS transistors, with implanted dopants used to adjust the work function. During the annealing process to fully silicide the gate electrode, however, the implanted dopants can interact with the gate dielectric. This can result in the same type of threshold voltage (Vₜ) offset problem encountered for doped polysilicon. There is also the potential for nickel atoms to migrate into the gate dielectric and channel, thereby introducing defects that can degrade the performance, reliability, and stability of the device over time.

Others have attempted to use a single mid gap metal gate electrode with a fixed work function to set the correct threshold voltage (Vₜ). Mid gap means that the work function is about mid-way between the valence band and the conduction band of the substrate. However, such mid-gap materials are unsatisfactory in a CMOS device, or other settings, where it is desirable to adjust the work function, in order to achieve multiple threshold voltage (Vₜ) values or lower threshold voltage (Vₜ) values to improve I drive. Furthermore, if the metal gate work function is not at the dead center of the silicon band gap, asymmetrical threshold voltage (Vₜ) values will result between PMOS and NMOS devices.

Accordingly, what is needed in the art is a new MOS device, method of manufacture therefore, and integration scheme that allows multiple and symmetrical threshold voltage (Vₜ) values to be set on the same chip, without experiencing the drawbacks of the prior art MOS devices.

### SUMMARY OF THE INVENTION

To address the above-discussed deficiencies of the prior art, the present invention provides a metal oxide semiconductor (MOS) device, a method of manufacture therefore, and an integrated circuit including the same. The metal oxide semiconductor (MOS) device, without limitation, may include a first accumulation mode transistor device located over or in a substrate, as well as a second enhancement mode transistor device located over or in the substrate. The method for manufacturing the metal oxide semiconductor (MOS) device, in one exemplary embodiment, includes forming these two features. Similarly, the integrated circuit, in addition to these two features, may include dielectric layers located over these features, as well as interconnects located within the dielectric layers and contacting the features to form an operational integrated circuit.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a cross-sectional view of one embodiment of a metal oxide semiconductor (MOS) device that has been manufactured in accordance with the principles of the present invention;

FIG. 2 illustrates a cross-sectional view of an alternative embodiment of a MOS device manufactured in accordance with the principles of the present invention;

FIG. 3 illustrates a cross-sectional view of an alternative embodiment of a MOS device manufactured in accordance with the principles of the present invention;

FIG. 4 illustrates a cross-sectional view of an embodiment of a MOS device at an initial stage of manufacture;

FIG. 5 illustrates a cross-sectional view of the partially completed MOS device illustrated in FIG. 4, after protecting the first accumulation mode transistor device region and second enhancement mode transistor device region using a photoresist layer or mask;

FIG. 6 illustrates a cross-sectional view of the partially completed MOS device illustrated in FIG. 5 after removing the photoresist layer or mask and conventionally forming isolation structures and gate structures; and

FIG. 7 illustrates a cross-sectional view of a conventional integrated circuit (IC) incorporating a MOS device constructed according to the principles of the present invention.

### DETAILED DESCRIPTION

The present invention is based, at least in part, on the unique recognition that accumulation mode transistor devices and enhancement mode transistor devices may be formed over or in the same substrate to achieve unexpected operating results. The present invention has further recognized that this previously unrealized implementation may be used to provide multiple symmetrical threshold voltages (Vₜₛ) over or in the same substrate. Moreover, the unique implementation of the present invention enables multiple threshold voltages (Vₜₛ) on the same chip without needing to rely on tunable work function metal gates. Further, the implementation may be easily tailored with limited, if any, additional processing steps, to provide up to about eight different threshold voltages (Vₜₛ) on the same chip. Additionally, it is applicable for both metal gate electrodes and polysilicon gate electrodes.

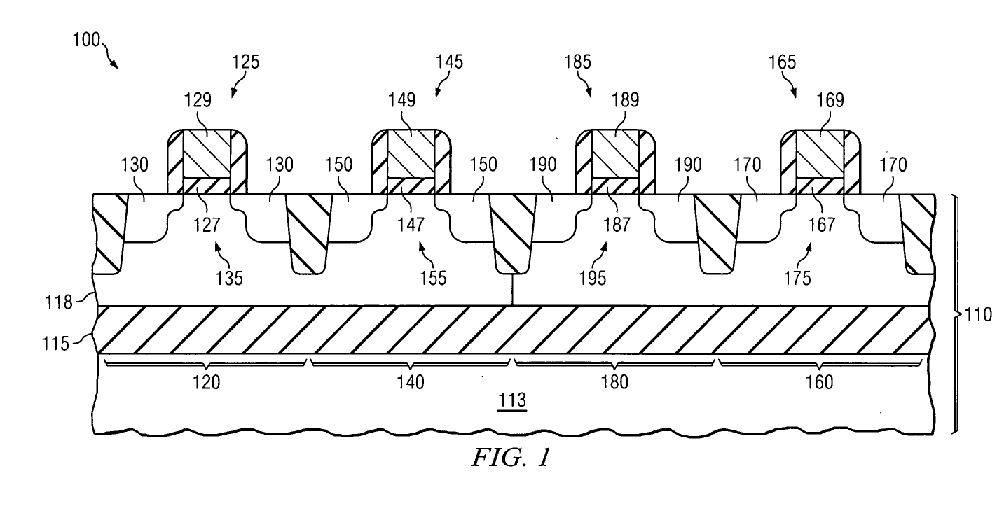

Turning now to FIG. 1, illustrated is a cross-sectional view of one embodiment of a metal oxide semiconductor (MOS) device 100 that has been manufactured in accordance with the principles of the present invention. The MOS device 100 illustrated in FIG. 1 initially includes a substrate 110. The substrate 110 may comprise one or a combination of different layers over/on/in which the features of the MOS device 100 may be formed. For example, in the given embodiment of FIG. 1, the substrate 110 comprises a wafer layer 113, an insulator layer 115, and a silicon (e.g., epitaxial silicon) layer 118. This embodiment might be used if the MOS device 100 was a fully depleted silicon-on-insulator MOSFET. Another embodiment might exist wherein the substrate 110 only comprised the silicon layer 118 formed on the wafer 113. This embodiment might be used if the MOS device 100 was a multi-gate MOSFET. Still another embodiment might exist wherein the substrate 110 was only the silicon layer 118. Accordingly, many different embodiments may exist for the substrate 110, and therefore the present invention is not limited to that shown in FIG. 1.

Located over or in the substrate 110 is a first accumulation mode transistor device 120, a second enhancement mode transistor device 140, a third accumulation mode transistor device 160 and a fourth enhancement mode transistor device 180. While four transistor devices 120, 140, 160, 180 are illustrated in the embodiment of FIG. 1, the MOS device 100 could just as easily be manufactured just having the first accumulation mode transistor device 120 and second enhancement mode transistor device 140. Just the same, other embodiments exist wherein the MOS device 100 includes more than just the four transistor devices 120, 140, 160, 180. Nevertheless, in the given embodiment of FIG. 1, the first accumulation mode transistor device 120 more specifically comprises a first PMOS accumulation mode transistor device, the second enhancement mode transistor device 140 more specifically comprises a second NMOS enhancement mode transistor device, the third accumulation mode transistor device 160 more specifically comprises a third NMOS accumulation mode transistor device, and the fourth enhancement mode transistor device 180 more specifically comprises a fourth PMOS enhancement mode transistor device.

As those skilled in the art are generally aware, accumulation mode devices typically have a similar type of dopant in the source/drain regions as the channel region located therebetween. On the contrary, enhancement mode devices typically have an opposite type of dopant in the source/drain regions than the channel region located therebetween. Therefore, an accumulation mode PMOS transistor device would typically have source/channel/drain dopant scheme of P+/P−/P+, an accumulation mode NMOS transistor device would typically have a source/channel/drain dopant scheme of N+/N−/N+, an enhancement mode PMOS transistor device would typically have a source/channel/drain dopant scheme of P+/N−/P+, and an enhancement mode NMOS transistor device would typically have a source/channel/drain dopant scheme of N+/P−/N+.

Referring back to FIG. 1, the first accumulation mode transistor device 120, second enhancement mode transistor device 140, third accumulation mode transistor device 160 and fourth enhancement mode transistor device 180 each include a gate structure 125, 145, 165, 185, respectively. Similarly, each of the gate structures 125, 145, 165, 185 include both a gate dielectric 127, 147, 167, 187, respectively, as well as a gate electrode 129, 149, 169, 189, respectively.

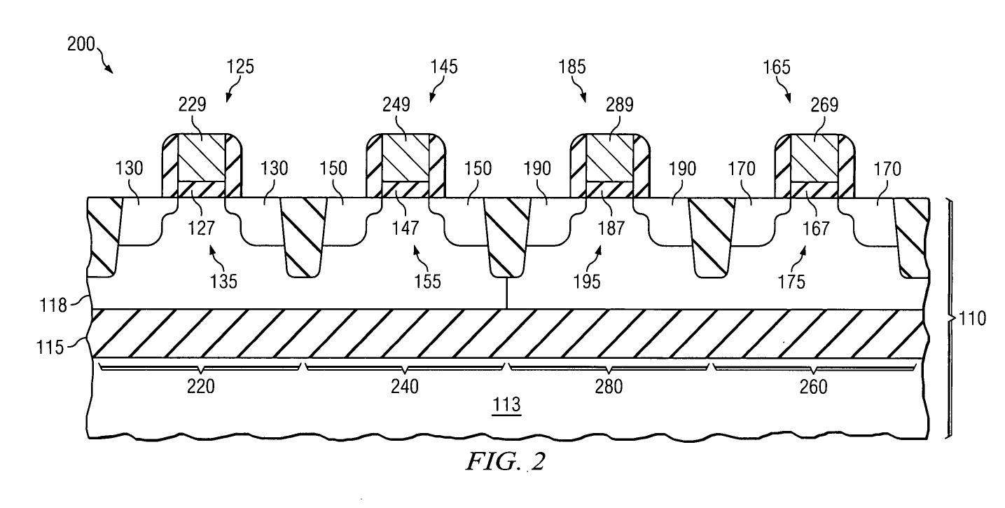

Unique to the embodiment of FIG. 1, each of the gate electrodes 129, 149, 169, 189 comprises a similar gate electrode material having a near mid gap gate electrode work function. Mid gap, as defined herein, refers to a gate electrode work function of about 4.7 eV. Accordingly, a near mid gap gate electrode work function would not be 4.7 eV, but would be close to 4.7 eV. For example, in the exemplary embodiment shown in FIG. 1 the near mid gap gate electrode work function ranges from about 4.3 eV to about 4.6 eV. However, in the exemplary embodiment of FIG. 2 (see below) the near mid gap gate electrode work function ranges from 4.8 eV to about 5.1 eV.

Those skilled in the art understand the types of materials and processes that could be used to form the gate electrodes 129, 149, 169, 189 having the near mid gap work function ranging from about 4.3 eV to about 4.6 eV. In one known embodiment, however, the gate electrodes 129, 149, 169, 189 is a metal gate electrode comprising titanium nitride configured to have a near mid gap work function in the aforementioned range. While titanium nitride has been given as one example of the gate electrode 129, 149, 169, 189 material, those skilled in the art appreciate that other materials might be used.

Located within the silicon layer 118 of the substrate 110 below each of the gate structure 125, 145, 165, 185 are source/drain regions 130, 150, 170, 190, respectively. The source/drain regions 130, 150, 170, 190, as one would expect, are located proximate channel regions 135, 155, 175, 195, respectively. Given the indication that the first accumulation mode transistor device 120 comprises a first PMOS accumulation mode transistor device, the second enhancement mode transistor device 140 comprises a second NMOS enhancement mode transistor device, the third accumulation mode transistor device 160 comprises a third NMOS accumulation mode transistor device, and the fourth enhancement mode transistor device 180 comprises a fourth PMOS enhancement mode transistor device, the source/drain regions 130, 150, 170, 190, and channel regions 135, 155, 175, 195, may be doped according to the dopant schemes discussed above.

When the source/drain regions 130, 150, 170, 190, and channel regions 135, 155, 175, 195, are doped according to the dopant schemes discussed above, and the gate electrodes 129, 149, 169, 189 have a near mid gap gate electrode work function ranging from about 4.3 eV to about 4.6 eV, the first PMOS accumulation mode transistor device 120 and second NMOS enhancement mode transistor device 140 should have low threshold voltages (Vₜₛ) (e.g., threshold voltages (Vₜₛ) ranging from about 0.1 volts to about 0.3 volts). Similarly, the third NMOS accumulation mode transistor device 160 and fourth PMOS enhancement mode transistor device 180 should have high threshold voltages (Vₜₛ) (e.g., threshold voltages (Vₜₛ) ranging from about 0.3 volts to about 0.6 volts). As is well known in the art, the low threshold voltage (Vₜ) devices typically provide high performance devices and the high threshold voltage (Vₜ) devices typically provide low power devices.

Turning now to FIG. 2, illustrated is a cross-sectional view of an alternative embodiment of a MOS device 200 manufactured in accordance with the principles of the present invention. The MOS device 200 illustrated in FIG. 2 is substantially similar to the MOS device 100 illustrated in FIG. 1 but for a few differences. Accordingly, where like reference numerals are used for both FIG. 1 and FIG. 2, the features are substantially similar.

The major difference between the MOS device 200 illustrated in FIG. 2 and the MOS device 100 illustrated in FIG. 1 remains in the fact that the gate electrodes 229, 249, 269, 289 of FIG. 2 have a near mid gap gate electrode work function ranging from about 4.8 eV to about 5.1 eV, wherein the gate electrodes 129, 149, 169, 189 of FIG. 1 have a near mid gap gate electrode work function ranging from about 4.3 eV to about 4.6 eV. As those skilled in the art are aware, the change in near mid gap electrode work function of the gate electrodes 229, 249, 269, 289, may be accomplished by changing the gate electrode material or the process for forming the gate electrodes 229, 249, 269, 289.

However, when the source/drain regions 130, 150, 170, 190, and channel regions 135, 155, 175, 195, are doped according to the dopant schemes discussed above, and the gate electrodes 229, 249, 269, 289 have a near mid gap gate electrode work function ranging from about 4.8 eV to about 5.1 eV, the first PMOS accumulation mode transistor device 220 and second NMOS enhancement mode transistor device 240 should have high threshold voltages (Vₜₛ) (e.g., threshold voltages (Vₜₛ) ranging from about 0.3 volts to about 0.6 volts). Similarly, the third NMOS accumulation mode transistor device 260 and fourth PMOS enhancement mode transistor device 280 should have low threshold voltages (Vₜₛ) (e.g., threshold voltages (Vₜₛ) ranging from about 0.1 volts to about 0.3 volts). Accordingly, by just changing the near mid gap gate electrode work function from about 4.3 eV to about 4.6 eV (FIG. 1) to about 4.8 eV to about 5.1 eV (FIG. 2), four different threshold voltages (Vₜₛ) may be achieved.

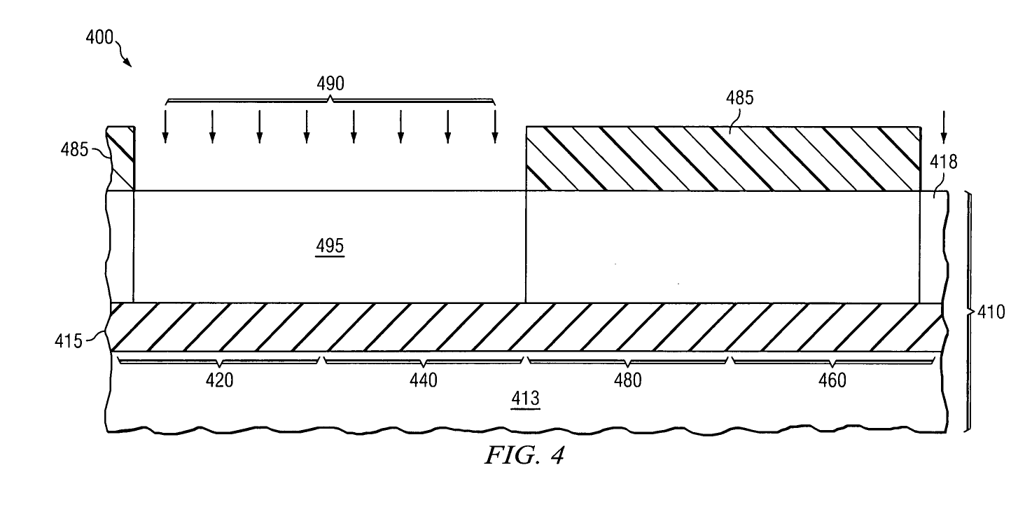

Another embodiment of the invention places devices similar to those of FIGS. 1 and 2 on the same substrate. In this embodiment, eight different threshold voltages (Vₜₛ) may easily be achieved. As will be understood later below with respect to FIGS. 4-6, the process for manufacturing these devices is simple.

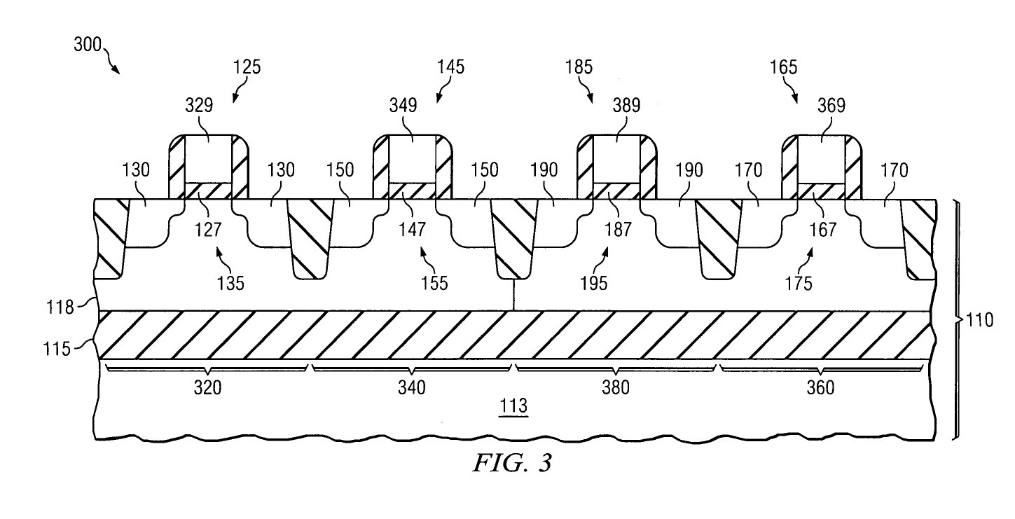

Turning now to FIG. 3, illustrated is a cross-sectional view of an alternative embodiment of a MOS device 300 manufactured in accordance with the principles of the present invention. The MOS device 300 illustrated in FIG. 3 is substantially similar to the MOS devices 100, 200 illustrated in FIGS. 1 and 2, respectively. Accordingly, where like reference numerals are used for both FIGS. 1, 2 and 3, the features are substantially similar.

The major difference between the MOS device 300 illustrated in FIG. 3 and the MOS devices 100, 200 illustrated in FIGS. 1 and 2 remains in the fact that the gate electrodes 329, 349, 369, 389 of FIG. 2 are polysilicon gate electrodes. As those skilled in the art are aware, the use of polysilicon for the gate electrodes 329, 349, 369, 389 changes their work function. Thus, when the source/drain regions 130, 150, 170, 190, and channel regions 135, 155, 175, 195, are doped according to the dopant schemes discussed above, and the gate electrodes 329, 349, 369, 389 comprise polysilicon, the first PMOS accumulation mode transistor device 320 and third NMOS accumulation mode transistor device 360 should have high threshold voltages (Vₜₛ) (e.g., threshold voltages (Vₜₛ) ranging from about 0.3 volts to about 0.6 volts). Similarly, the second NMOS enhancement mode transistor device 340 and fourth PMOS enhancement mode transistor device 380 should act as native devices, thereby having threshold voltages (Vₜₛ) substantially equal, if not equal, to zero.

The embodiments of FIGS. 1-3 illustrated a specific placement for the different accumulation mode transistor devices and enhancement mode transistor devices. Nevertheless, the specific placement is not required to remain within the broad scope of the present invention. As one example of a different placement scheme, the accumulation mode devices could be placed beside one another and the enhancement mode devices placed beside one another, rather than alternating accumulation and enhancement mode devices as shown in FIGS. 1-3. Other modification could also be made.

Turning now to FIGS. 4-6, illustrated are cross-sectional views of detailed manufacturing steps instructing how one might, in an advantageous embodiment, manufacture a MOS device in accordance with the principles of the present invention. The embodiment illustrated with respect to FIGS. 4-6 represents a MOS device substantially similar to the MOS device 100 illustrated in FIG. 1. Nevertheless, the same principles could be used to manufacture a MOS device similar to that illustrated in FIGS. 2 and 3, or for that matter a different MOS device.

The partially completed MOS device 400 illustrated in FIG. 4 initially includes a substrate 410. As previously mentioned, the substrate 410 may comprise a variety of different layers. In this embodiment, however, the substrate comprises a wafer layer 413, an oxide layer 415, and a silicon (e.g., epitaxial silicon) layer 418. The oxide layer 415, in this embodiment should have an exemplary thickness ranging from about 50 nm to about 300 nm, with a preferred thickness ranging from about 100 nm to about 50 nm. Similarly, the silicon layer 418 should have an exemplary thickness ranging from about 5 nm to about 50 nm, with a preferred thickness ranging from about 10 nm to about 30 nm. Other substrate 410 thicknesses are, however, within the scope of the present invention.

The MOS device 400, as shown, may be divided into four different regions, including a first accumulation mode transistor device region 420, a second enhancement mode transistor device region 440, a third accumulation mode transistor device region 460 and fourth enhancement mode transistor device region 480. Located over the third accumulation mode transistor device region 460 and fourth enhancement mode transistor device region 480 and exposing the first accumulation mode transistor device region 420 and second enhancement mode transistor device region 440 is a photoresist layer or mask 485. This photoresist layer or mask 485 exposes the first accumulation mode transistor device region 420 and second enhancement mode transistor device region 440 to a first implant 490, thereby forming a first implant region 495.

The first implant 490, as used in accordance with this embodiment of the present invention, is a first p-type implant. One example of a p-type implant that might be used for the first implant 490 is boron. In one embodiment, the boron first implant 490 is implanted into the first accumulation mode transistor device region 420 and second enhancement mode transistor device region 440 resulting in a boron concentration ranging from about 1E15 atoms/cm³ to about 1E18 atoms/cm³, with a preferred value somewhere around about 1E17 atoms/cm³. As the silicon layer 418 is rather thin, this concentration would ideally be a uniform concentration. Those skilled in the art appreciated the process conditions that might be used to accomplish the aforementioned concentrations, including adjusting the implant power, temperature and dose. Those skilled in the art further recognize that the concentration may be changed from that discussed without departing from the scope of the present invention.

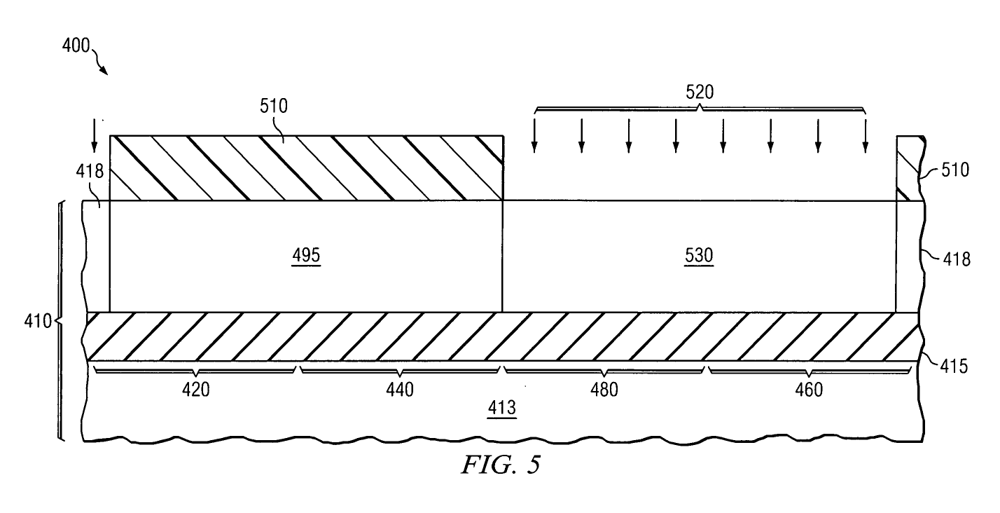

Turning now to FIG. 5, illustrated is a cross-sectional view of the partially completed MOS device 400 illustrated in FIG. 4, after protecting the first accumulation mode transistor device region 420 and second enhancement mode transistor device region 440 using a photoresist layer or mask 510. As is illustrated, the photoresist layer or mask 510 further exposes the third accumulation mode transistor device region 460 and fourth enhancement mode transistor device region 480 to a second implant 520, thereby forming a second implant region 530.

The second implant 520, as used in accordance with this embodiment of the present invention, is a second n-type implant. One example of an n-type implant that might be used for the second implant 520 is phosphorous. In one embodiment, the phosphorous second implant 520 is implanted into the third accumulation mode transistor device region 460 and fourth enhancement mode transistor device region 480 resulting in a phosphorous concentration ranging from about 1E15 atoms/cm³ to about 1E18 atoms/cm³, with a preferred value somewhere around about 1E17 atoms/cm³. Those skilled in the art again appreciated the process conditions that might be used to accomplish the aforementioned concentrations, including adjusting the implant power, temperature and dose. Again, those skilled in the art recognize that the concentration may be changed from that discussed without departing from the scope of the present invention.

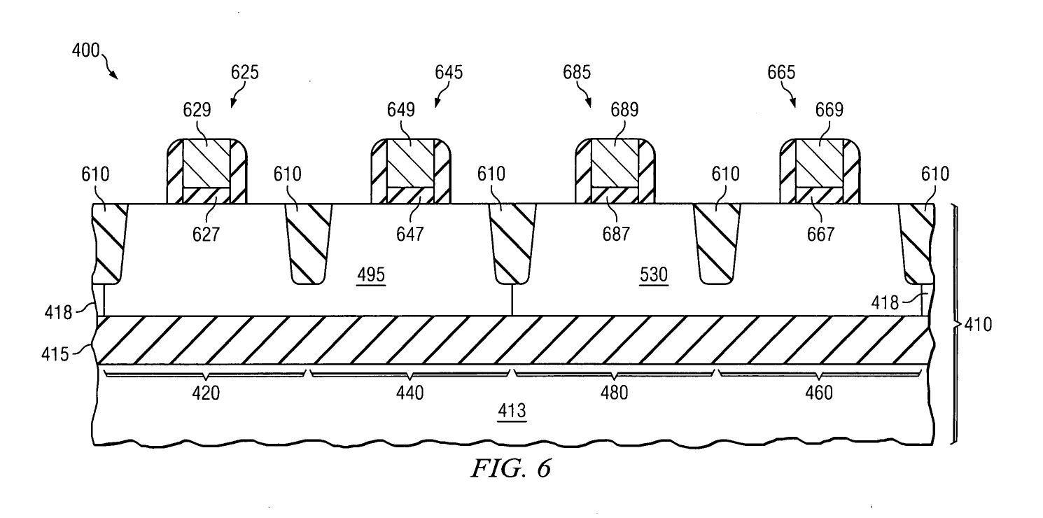

Turning now to FIG. 6, illustrated is a cross-sectional view of the partially completed MOS device 400 illustrated in FIG. 5 after removing the photoresist layer or mask 510 and conventionally forming isolation structures 610 and gate structures 625, 645, 665, 685. As with the embodiment of FIG. 1, the gate structures 625, 645, 665, 685 may be conventionally formed to have gate dielectric layers 627, 647, 667, 687, respectively, and gate electrodes 629, 649, 669, 689, respectively. Those skilled in the art understand the process that could be used to form the gate structures 625, 645, 665, 685, including forming a blanket layer of gate dielectric material and a blanket layer of gate electrode material, which in this embodiment has a near mid gap work function ranging from about 4.3 eV to about 4.6 eV, and thereafter patterning the blanket layers to form the gate structures 625, 645, 665, 685.

After conventionally forming the gate structures 625, 645, 665, 685, the manufacturing process would continue until a device similar to the MOS device 100 illustrated in FIG. 1 was obtained. These additional conventional steps might include, without limitation, forming source/drain regions, pocket or HALO implants, gate sidewall spacers, etc.

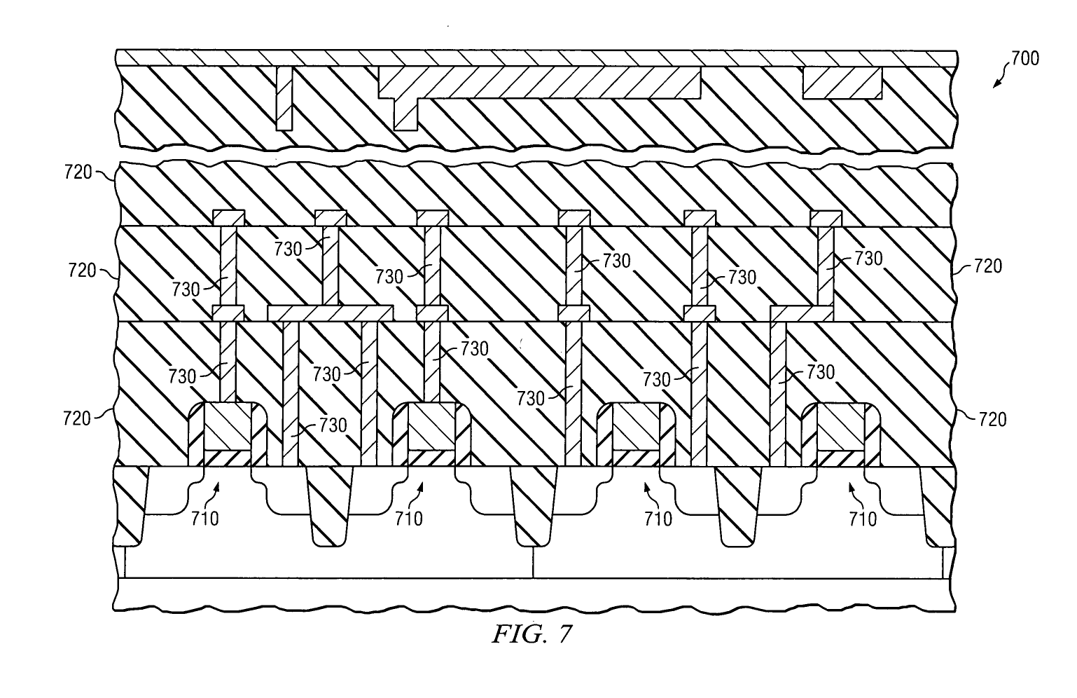

Referring finally to FIG. 7, illustrated is a cross-sectional view of a conventional integrated circuit (IC) 700 incorporating a MOS device 710 constructed according to the principles of the present invention. The IC 700 may include devices, such as transistors used to form CMOS devices, BiCMOS devices, Bipolar devices, or other types of devices. The IC 700 may further include passive devices, such as inductors or resistors, or it may also include optical devices or optoelectronic devices. Those skilled in the art are familiar with these various types of devices and their manufacture. In the particular embodiment illustrated in FIG. 7, the IC 700 includes the MOS device 710 having dielectric layers 720 located thereover. Additionally, interconnect structures 730 are located within the dielectric layers 720 to interconnect various devices, thus, forming the operational integrated circuit 700.

Although the present invention has been described in detail, those skilled in the art should understand that they could make various changes, substitutions and alterations herein without departing from the spirit and scope of the invention in its broadest form.

What is claimed is:

1. A metal oxide semiconductor (MOS) device, comprising:
a first accumulation mode transistor device located over or in a substrate; and
a second enhancement mode transistor device located over or in the substrate.

2. The metal oxide semiconductor (MOS) device as recited in claim 1 wherein the first accumulation mode transistor device and the second enhancement mode transistor device each have a near mid gap gate electrode work function.

3. The metal oxide semiconductor (MOS) device as recited in claim 2 wherein the near mid gap gate electrode work function ranges from about 4.3 eV to about 4.6 eV.

4. The metal oxide semiconductor (MOS) device as recited in claim 3 wherein the first accumulation mode transistor device is a first PMOS accumulation mode transistor device and wherein the second enhancement mode transistor device is a second NMOS enhancement mode transistor device.

5. The metal oxide semiconductor (MOS) device as recited in claim 4 wherein the first PMOS accumulation mode transistor device and the second NMOS enhancement mode transistor device are low threshold voltage (Vₜ) devices.

6. The metal oxide semiconductor (MOS) device as recited in claim 5 further including a third NMOS accumulation mode transistor device and a fourth PMOS enhancement mode transistor device located over or in the substrate.

7. The metal oxide semiconductor (MOS) device as recited in claim 6 wherein the third NMOS accumulation mode transistor device and the fourth PMOS enhancement mode transistor device are high threshold voltage (Vₜ) devices.

8. The metal oxide semiconductor (MOS) device as recited in claim 3 wherein the first accumulation mode transistor device is a first NMOS accumulation mode transistor device and wherein the second enhancement mode transistor device is a second PMOS enhancement mode transistor device.

9. The metal oxide semiconductor (MOS) device as recited in claim 8 wherein the first NMOS accumulation mode transistor device and the second PMOS enhancement mode transistor device are high threshold voltage (Vₜ) devices.

10. The metal oxide semiconductor (MOS) device as recited in claim 2 wherein the near mid gap gate electrode work function ranges from about 4.8 eV to about 5.1 eV.

11. The metal oxide semiconductor (MOS) device as recited in claim 10 wherein the first accumulation mode transistor device is a first NMOS accumulation mode transistor device and wherein the second enhancement mode transistor device is a second PMOS enhancement mode transistor device.

12. The metal oxide semiconductor (MOS) device as recited in claim 11 wherein the first PMOS accumulation mode transistor device and the second NMOS enhancement mode transistor device are high threshold voltage (Vₜ) devices.

13. The metal oxide semiconductor (MOS) device as recited in claim 12 further including a third NMOS accumulation mode transistor device and a fourth PMOS enhancement mode transistor device located over or in the substrate.

14. The metal oxide semiconductor (MOS) device as recited in claim 13 wherein the third NMOS accumulation mode transistor device and the fourth PMOS enhancement mode transistor device are low threshold voltage (Vₜ) devices.

15. The metal oxide semiconductor (MOS) device as recited in claim 10 wherein the first accumulation mode transistor device is a first NMOS accumulation mode transistor device and wherein the second enhancement mode transistor device is a second PMOS enhancement mode transistor device.

16. The metal oxide semiconductor (MOS) device as recited in claim 15 wherein the first NMOS accumulation mode transistor device and the second PMOS enhancement mode transistor device are low threshold voltage (Vₜ) devices.

17. The metal oxide semiconductor (MOS) device as recited in claim 1 wherein the first accumulation mode transistor device and the second enhancement mode transistor device each comprise polysilicon gate electrodes and wherein the first accumulation mode transistor device is a high threshold voltage (Vₜ) device and the second enhancement mode transistor device is a native device having a threshold voltage (Vₜ) substantially equal to zero.

18. The metal oxide semiconductor (MOS) device as recited in claim 1 wherein the first accumulation mode transistor device or the second enhancement mode transistor device forms at least a portion of a fully depleted silicon-on-insulator MOSFET or a multi-gate MOSFET.

19. A method for manufacturing a metal oxide semiconductor (MOS) device, comprising:
forming a first accumulation mode transistor device over or in a substrate; and
forming a second enhancement mode transistor device over or in the substrate.

20. The method as recited in claim 19 wherein the first accumulation mode transistor device and the second enhancement mode transistor device each have a near mid gap gate electrode work function.

21. The method as recited in claim 20 wherein the near mid gap gate electrode work function ranges from about 4.3 eV to about 4.6 eV.

22. The method as recited in claim 21 wherein the first accumulation mode transistor device is a first PMOS accumulation mode transistor device and wherein the second enhancement mode transistor device is a second NMOS enhancement mode transistor device.

23. The method as recited in claim 22 wherein the first PMOS accumulation mode transistor device and the second NMOS enhancement mode transistor device are low threshold voltage (Vₜ) devices.

24. The method as recited in claim 23 further including forming a third NMOS accumulation mode transistor device and a fourth PMOS enhancement mode transistor device over or in the substrate.

25. The method as recited in claim 24 wherein the third NMOS accumulation mode transistor device and the fourth PMOS enhancement mode transistor device are high threshold voltage (Vₜ) devices.

26. The method as recited in claim 21 wherein the first accumulation mode transistor device is a first NMOS accumulation mode transistor device and wherein the second enhancement mode transistor device is a second PMOS enhancement mode transistor device.

27. The method as recited in claim 26 wherein the first NMOS accumulation mode transistor device and the second PMOS enhancement mode transistor device are high threshold voltage (Vₜ) devices.

28. The method as recited in claim 20 wherein the near mid gap gate electrode work function ranges from about 4.8 eV to about 5.1 eV.

29. The method as recited in claim 28 wherein the first accumulation mode transistor device is a first PMOS accumulation mode transistor device and wherein the second enhancement mode transistor device is a second NMOS enhancement mode transistor device.

30. The method as recited in claim 29 wherein the first PMOS accumulation mode transistor device and the second NMOS enhancement mode transistor device are high threshold voltage (Vₜ) devices.

31. The method as recited in claim 30 further including forming a third NMOS accumulation mode transistor device and a fourth PMOS enhancement mode transistor device over or in the substrate.

32. The method as recited in claim 31 wherein the third NMOS accumulation mode transistor device and the fourth PMOS enhancement mode transistor device are low threshold voltage (Vₜ) devices.

33. The method as recited in claim 28 wherein the first accumulation mode transistor device is a first NMOS accumulation mode transistor device and wherein the second enhancement mode transistor device is a second PMOS enhancement mode transistor device.

34. The method as recited in claim 33 wherein the first NMOS accumulation mode transistor device and the second PMOS enhancement mode transistor device are low threshold voltage (Vₜ) devices.

35. The method as recited in claim 19 wherein the first accumulation mode transistor device and the second enhancement mode transistor device each comprise polysilicon gate electrodes and wherein the first accumulation mode transistor device is a high threshold voltage (Vₜ) device and the second enhancement mode transistor device is a native device having a threshold voltage (Vₜ) substantially equal to zero.

36. The method as recited in claim 19 wherein the first accumulation mode transistor device or the second enhancement mode transistor device forms at least a portion of a fully depleted silicon-on-insulator MOSFET or a multi-gate MOSFET.

37. An integrated circuit, comprising:
a first accumulation mode transistor device located over or in a substrate;
a second enhancement mode transistor device located over or in the substrate;
dielectric layers located over the first accumulation mode transistor device and the second enhancement mode transistor device; and
interconnects located within the dielectric layers and contacting the first accumulation mode transistor device and the second enhancement mode transistor device to form an operational integrated circuit.

38. The integrated circuit as recited in claim 37 wherein the first accumulation mode transistor device and the second enhancement mode transistor device each have a near mid gap gate electrode work function.

39. The integrated circuit as recited in claim 38 wherein the first accumulation mode transistor device is a first PMOS accumulation mode transistor device and wherein the second enhancement mode transistor device is a second NMOS enhancement mode transistor device.

40. The integrated circuit as recited in claim 38 wherein the first accumulation mode transistor device is a first NMOS accumulation mode transistor device and wherein the second enhancement mode transistor device is a second PMOS enhancement mode transistor device.

41. The integrated circuit as recited in claim 37 wherein the first accumulation mode transistor device and the second enhancement mode transistor device each comprise polysilicon gate electrodes and wherein the first accumulation mode transistor device is a high threshold voltage (Vₜ) device and the second enhancement mode transistor device is a native device having a threshold voltage (Vₜ) substantially equal to zero.

42. The integrated circuit as recited in claim 37 wherein the first accumulation mode transistor device or the second enhancement mode transistor device forms at least a portion of a fully depleted silicon-on-insulator MOSFET or a multi-gate MOSFET.
